(19) United States
(12) Patent Application Publication
(10) Pub. No.: US 2014/0232398 A1
(43) Pub. Date: Aug. 21, 2014

(54) METHODS AND APPARATUS FOR COMPENSATING FOR DRIFT IN MAGNETIC FIELD STRENGTH IN SUPERCONDUCTING MAGNETS

(71) Applicant: Nicholas Paul Aley, Witney (GB)

(72) Inventor: Nicholas Paul Aley, Witney (GB)

(21) Appl. No.: 14/185,332

(22) Filed: Feb. 20, 2014

(30) Foreign Application Priority Data
Feb. 20, 2013 (GB) 1302980.6

(51) Int. Cl. G01R 33/3873; G01R 33/3815

(52) U.S. Cl. CPC G01R 33/3873; G01R 33/3815
USPC 324/309; 324/322

(57) ABSTRACT

An MRI system has compensating material located at a radial position between the imaging region and the basic field magnet in a location that will be heated over a range of temperatures during operation of the MRI system. The compensating material has a magnetic susceptibility that varies with temperature over the range of temperatures in a manner opposite to the variation in magnetic susceptibility of the material of the OVC bore tube of the basic field magnet over the range of temperatures.

### BACKGROUND OF THE INVENTION

1. Field of the Invention

The present invention relates to a method and an apparatus to compensate for drift in magnetic field strength in superconducting magnets, particularly drift caused by thermal variation of magnetic properties.

2. Description of the Prior Art

FIG. 1 illustrates a schematic radial cross-section through a typical superconducting magnet structure used in an MRI system, such as may be improved by the present invention. A cylindrical magnet 10, typically has superconducting coils mounted on a former or other mechanical support structure, and is positioned within a cryostat, having a cryogen vessel 12 that contains a quantity of liquid cryogen 15, for example helium, which holds the superconducting magnet at a temperature below its transition temperature. The magnet is essentially rotationally symmetrical about a longitudinal axis A-A. The term “axial” is used in the present document to indicate a direction parallel to axis A-A, while the term “radial” means a direction perpendicular to axis A-A, in a plane which passes through the axis A-A.

The cryogen vessel 12 is itself cylindrical, having an outer cylindrical wall 12a, an inner cylindrical bore tube 12b, and substantially planar annular end caps (not visible in FIG. 1). An outer vessel 14 surrounds the cryogen vessel. It is commonly referred to as Outer Vacuum Chamber (OVC), and will be referred to herein as OVC. The OVC 14 is also cylindrical, having an outer cylindrical wall 14a, an inner cylindrical bore tube 14b, and substantially planar annular end caps (not visible in FIG. 1). A hard vacuum is provided in the volume between the OVC 14 and the cryogen vessel 12, providing effective thermal insulation. A thermal radiation shield 16 is placed in the evacuated volume. This is typically not a fully closed vessel, but is essentially cylindrical, having an outer cylindrical wall 16a, an inner cylindrical bore tube 16b, and substantially planar annular end caps (not visible in FIG. 1). The thermal radiation shield 16 serves to intercept radiated heat from the OVC 14 before it reaches the cryogen vessel 12. The thermal radiation shield 16 is cooled, for example by an active cryogenic refrigerator 17, or by escaping cryogen vapour.

In alternative arrangements, the magnet is not housed within a cryogen vessel, but is cooled in some other way: either by a low cryogen inventory arrangement such as a cooling loop, or a ‘dry’ arrangement in which a cryogenic refrigerator is thermally linked to the magnet. In ‘dry’ configurations, heat loads on the magnet are not directly cooled by liquid cryogens but, instead, are removed via a thermal link connected to a cooling pipe or refrigerator. Such heat-loads can result, for instance, from current ramping or gradient coil operation. The OVC is however still present.

The OVC bore tube 14b must be mechanically strong and vacuum tight, to withstand vacuum loading both radially and axially. Conventionally, it is made of stainless steel. The cryogen vessel bore tube 12b, if any, must be strong and capable of withstanding the pressure of cryogen gas within the cryogen vessel. Typically, this is also of stainless steel. The bore tube 16b of the thermal radiation shield 16 must be impervious to infra-red radiation. It is preferably lightweight and a good conductor of heat. It is typically made of aluminum.

In order to provide an imaging capability, a set of gradient coils 20 (not visible in FIG. 1) are provided within a gradient coil assembly 22 mounted within the OVC bore 14b. A gradient coil assembly 22 usually has a hollow cylindrical, resin-impregnated block, containing coils which generate orthogonal oscillating magnetic field gradients in three dimensions and slots 24 for positioning of shims for correction of inhomogeneity in the background magnetic field. A patient bore 25, located within the gradient coil assembly 22, is an open volume into which a patient is placed for imaging. A shimming arrangement is typically provided within the gradient coil assembly 22, where passive iron shims are placed in selected locations to improve the homogeneity of the background field B₀ in the imaging region. Typically, the shims are placed in trays (not shown) which are, in turn, placed within shim slots 24.

During an imaging procedure, the gradient coils 20 generate rapidly oscillating magnetic fields with very fast rise-times of typically just a few milliseconds. Stray fields from the gradient coils generate eddy currents in metal parts of the cryostat, in particular in metal bore tubes 14b, 16b, 12b of OVC, thermal shield and cryogen vessel. These eddy currents cause ohmic heating of the OVC bore tube. Mechanical vibration of the gradient coil causes vibration of the OVC bore tube. As this vibration takes place within the magnetic field of the superconducting magnet 10, further currents are induced in the material of the OVC bore tube, causing further heating. The gradient coils themselves are made of resistive wire, typically copper, and heat significantly in use.

These factors combine to produce an appreciable heating of the OVC bore tube. Cryogen vessel 12 and thermal radiation shield 16 are cooled by liquid cryogen 15, where used, and refrigerator 17. They do not heat appreciably when the magnet is in use.

The superconducting magnet 10 operates in persistent mode and generates a constant magnetic field, which may be referred to as the “background field” B₀.

An imaging region 30 is provided, typically near the radial and axial centre of the patient bore 25. Great care is taken to ensure that the background field B₀ is homogeneous and constant throughout the volume of the imaging region. This is typically designed and achieved to within a few parts per million.

However, some temporal drift in both the homogeneity and field strength of the background field B₀ is observed with time, when the MRI system is in use. This has been attributed to changes of magnetic properties of the material of the OVC bore tube 14b with varying temperature. The heating of the OVC and shims will cause higher order drifts leading to reduced homogeneity.

When the MRI system is in use, the OVC bore tube 14b is heated by conduction and radiation from the gradient coil assembly, and is heated by eddy currents caused by mechanical oscillation of the OVC tube, itself caused by interaction with time varying magnetic fields generated by the gradient coil assembly, as explained above.

### SUMMARY OF THE INVENTION

The present invention accordingly provides a method and apparatus for compensating for such variation in magnetic properties of the materials of the bore tubes.

This object is achieved by an MRI system according to the invention that has compensating material located at a radial position between the imaging region and the basic field magnet in a location that will be heated over a range of temperatures during operation of the MRI system. The compensating material has a magnetic susceptibility that varies with temperature over the range of temperatures in a manner opposite to the variation in magnetic susceptibility of the material of the OVC bore tube of the basic field magnet over the range of temperatures.

The above object is achieved in accordance with the invention by a method that includes situating compensating material at a radial position between the imaging region and the basic field magnet in a location that will be heated over a range of temperatures during operation of the MRI system. The compensating material is selected to as to have a magnetic susceptibility that varies with temperature over the range of temperatures in a manner opposite to the variation in magnetic susceptibility of the material of the OVC bore tube of the basic field magnet over the range of temperatures.

### BRIEF DESCRIPTION OF THE DRAWINGS

FIG. 1 illustrates a schematic cross-section through a typical superconducting magnet structure used in an MRI system.

FIG. 2 shows calculated contributions to drift in background magnetic field B₀ due to variation in magnetic properties in OVC bore tubes of three different compositions over a temperature variation of 5K.

FIG. 3 illustrates the variation in magnetic susceptibility of nickel-iron vanadates as a function of temperature and of composition.

FIG. 4 illustrates the variation in magnetic susceptibility of iron-nickel-manganese alloys as a function of temperature and of composition.

### DESCRIPTION OF THE PREFERRED EMBODIMENTS

It has been found that a significant portion of the observed variation in background field variation (“drift”) ΔB₀ is caused by the effect of heating the OVC bore tube 14b. This in turn is believed to be attributable to a change of the magnetic properties of the material of the OVC bore tube 14b due to changes in its temperature. The proportion of the B₀ drift attributed to the changes in magnetic properties of the material of the OVC bore tube will depend on a number of factors. Temperature rise of the bore tube compared to the temperature rise of the shims. It will vary with the volume/mass of OVC that is heated, and the distribution of shim iron. The contribution of background field variation (“drift”) ΔB₀ which is caused by the effect of heating the OVC bore tube 14b will dominate as the B₀ field increases.

Typically, the OVC bore tube 14b is made of stainless steel. Stainless steel is antiferromagnetic with an ordering (Néel) temperature of about 40K.

The susceptibility increases with temperature up till the ordering (Néel) temperature. Above that temperature the susceptibility follows a 1/T relationship.

Antiferromagnets have a small but positive susceptibility, and they do not exhibit ferromagnetic properties such as hysteresis. A typical temperature dependence of antiferromagnets is shown in FIG. 4.

The magnetization of the stainless steel will increase approximately linearly with field in the region of interest. The susceptibility of stainless steel varies with temperature, which is the cause of the B₀ drift.

Other materials such as aluminum or copper do not suffer from such temperature-dependent susceptibility, but are not commonly used for OVC bore tubes, due to a combination of higher electrical conductivity and higher cost, and lower load-bearing capability than stainless steel.

According to the present invention, one or more materials with complementary magnetic properties are added to a conventional OVC bore tube to compensate for thermal drift in the magnetic properties of the OVC bore tube.

In this way, thermal variation in the magnetic properties of the OVC bore tube 14b is compensated for by an opposing, complementary variation in magnetic properties in the added compensating material(s).

A typical OVC bore tube 14b is constructed of stainless steel, which has paramagnetic susceptibility due to the composition of the material itself, and also has a lesser ferromagnetic susceptibility, due to ferromagnetic phases induced by the mechanical cold working which the OVC has undergone in fabrication.

It has been found that the change in magnetic properties of the OVC is essentially due to thermal variation of the paramagnetic susceptibility. The ferromagnetic phases will also cause variation of the magnetic properties of the OVC bore tube, but this has been found to be of much less significance.

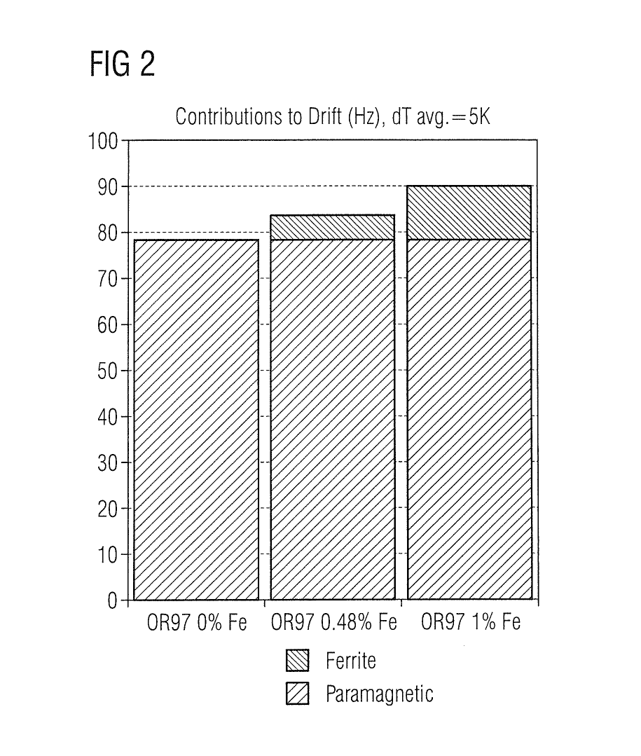

FIG. 2 shows calculated contributions to drift in background magnetic field B₀ due to variation in magnetic properties in OVC bore tubes of three different compositions over a temperature variation of 5K. The first composition has no ferromagnetic phase; the second composition has a ferromagnetic phase which accounts for 0.48% of the drift in background magnetic field B₀; and the third composition has a ferromagnetic phase which accounts for 1% of the drift in background magnetic field B₀. As can be clearly seen from this graph, the greatest scope for reduction in drift in background magnetic field B₀ can be addressed by compensating for drift in the paramagnetic susceptibility of the material of the OVC bore tube 14b.

Choice of an appropriate grade of stainless steel for the OVC bore tube would remove the ferromagnetic element of the B₀ drift. For example, a 304LN stainless steel, such as used for making helium vessels, or 310 or 904L stainless steels which produce negligible ferromagnetic phases on cold working. However, as illustrated in FIG. 2, this can only address a relatively small part of the B₀ drift. The present invention seeks a reduction in the B₀ drift caused by variation in paramagnetic susceptibility of the material of the OVC bore tube 14b.

The B₀ drift ΔB₀ is largely caused by reduced alignment of magnetic domains causing change in magnetic susceptibility Δχ with changing temperature ΔT. The B₀ drift ΔB₀ caused by the paramagnetic component of magnetic susceptibility of the stainless steel is proportional to the magnetic field H and the volume V of material:

$$\frac{Δ {B}_{0}}{Δ T} ∝ V . H . \frac{Δ χ}{Δ T} .$$

While the temperature dependence of the susceptibility of the material of the OVC bore tube 14b was not found to be a particular problem for superconducting magnets having a background field strength of about 1.5T, more recent MRI systems include superconducting magnets producing background field strength B₀ of 3T or more, and the temperature dependent susceptibility of the OVC bore tube has become a significant factor in observed B₀ field drift. The rise in magnetic moment of stainless steel is linear with magnetic field.

According to the present invention, a compensating material is added to the OVC bore tube. The compensating material reacts to the change in temperature ΔT by a change in magnetic susceptibility Δχ in the opposite direction from the change exhibited by the original material of the OVC bore tube.

The magnetization of the OVC bore tube changes due to the temperature dependence of the paramagnetic susceptibility of the stainless steel. In known stainless steels typically used for OVC bore tubes, the magnetization reduces with increasing temperature. In use, an OVC bore tube typically experiences variation in temperature of up to about 30K from room temperature. The change in magnetization over this range is approximately linear. The temperature change of the OVC depends on a large number of factors, such as design of the gradient coil assembly 22, the spacing between the gradient coil assembly and the OVC bore tube, the material of the bore tube, type of imaging sequence in operation. The heating is also inconsistent over the surface area of the OVC bore tube.

The paramagnetic susceptibility of stainless steel follows a Curie-Weiss Law:

$$χ ∝ \frac{1}{T - {T}_{c}}$$

The reduction in magnetization of the OVC bore tube with increasing temperature leads to a rise in B₀, temperature dependent drift.

Some materials are known to have a magnetic susceptibility which increases with temperature. According to an aspect of the present invention, specific masses of such materials may be added to the OVC bore tube at specific locations, and the increase in susceptibility of these materials with temperature will compensate for the reduction in susceptibility of the original material of the OVC bore tube to reduce the overall B₀ drift with temperature.

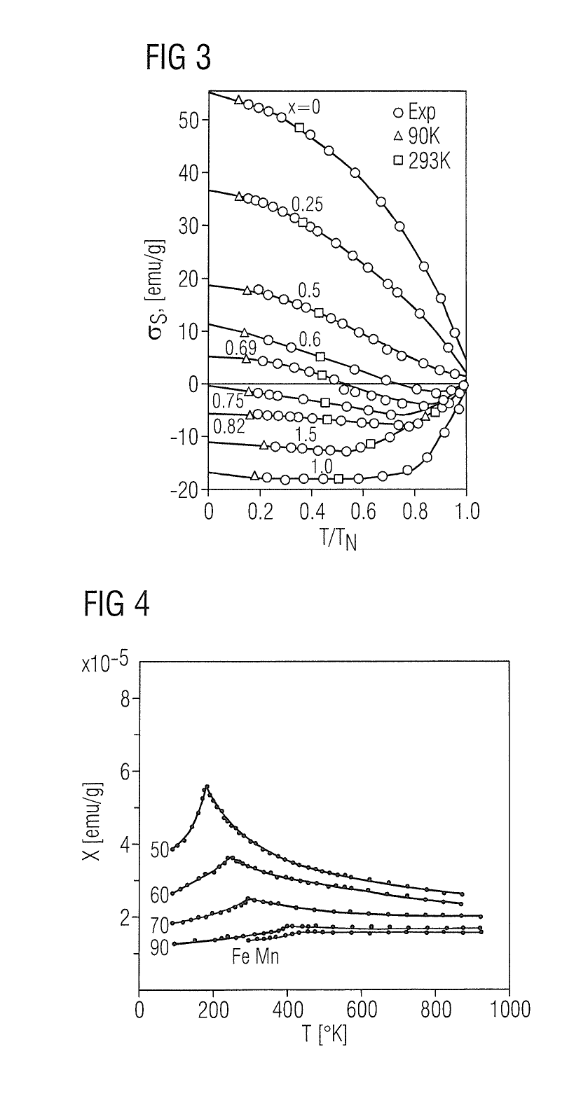

In an embodiment, ferrimagnetic nickel-iron vanadates (NiFe₂-xVₓO₄) may be used. Ferrimagnetic materials have a small positive magnetic susceptibility which increases with temperature. FIG. 3 illustrates changes in susceptibility sₛ which increases as its temperature approaches T_{N}, the Néel temperature [from “Modern Magnetic Materials: Principles and Applications”, by RC O'Handley, Wiley 2000 p 132 FIG. 4.9].

In an alternative embodiment, antiferromagnetic materials may be used. Antiferromagnetic materials have a small positive magnetic susceptibility which increases with temperature as its temperature approaches T_{N}, the Néel temperature. Antiferromagnetic materials include oxides such as nickel oxide NiO and alloys such as FeMn or NiFeMn, for example Fe₆₅(Ni₁₋ₓMnₓ)₃₅, particularly Fe₆₅(Ni₃₀Mn₇₀)₃₅. As illustrated in FIG. 4, susceptibility sₛ (here expressed as X) increases as its temperature approaches T_{N}, the Néel temperature. The various curves represent values of x in (Ni₁₋ₓMnₓ) [from Journal of the Physical society of Japan. “Magnetic Properties of Fe65(Ni1-xMnx)35 ternary alloys”, Masayuki Shiga p 539-546, Vol. 2, February 1967]. In the temperature range of interest (approximately 290 K-300 K), this is true only for Fe—Ni—Mn alloys with low Ni content.

In an embodiment, phase-change materials may be used. Such phase-change materials include FeRh (iron-rhodium). These materials exhibit a magnetic phase change from antiferromagnetic to ferromagnetic at a certain transition temperature. By selecting a phase-change material which has a transition temperature within the range of temperatures experienced by the OVC bore tube, such materials can compensate for the change in magnetic susceptibility of the original material of the OVC bore tube. Phase-change materials with a sharp transition temperature are known to be difficult to produce. Due to variations in composition, grain size, etc. commonly observed in real materials, phase-change materials usually exhibit a smooth increase in magnetization.

In preferred embodiments of the invention, the added compensating material is provided as a coating on the radially outer surface of the OVC bore tube—that is, the surface which is interior to the OVC.

For example, a paint containing the compensating material, such as NiO or NiFeMn, as a powder in an epoxy resin carrier may be applied to the radially outer surface of the OVC bore tube before the OVC is assembled. Application of the added compensating material to the radially outer surface of the OVC bore tube protects it from damage. However, since heating of the OVC bore tube is partially caused by radiant heat from a gradient coil assembly placed within the OVC bore tube, it may be found more effective to apply the added compensating material to the radially inner surface of the OVC bore tube, where it may experience temperature variations greater than the temperature variations experienced by the OVC bore tube.

Alternatively, the paint containing the compensating material may be applied to a radially outer surface of the gradient coil assembly 22. In some MRI systems, shim trays are positioned on a radially outer surface of the gradient coil assembly. In such arrangements, the compensating material of the present invention may be positioned on the outer surface of the gradient coil assembly, between the shim trays. By applying the compensating material to the gradient coil assembly, the compensating material will be subjected to a greater change in temperature than the OVC bore tube, but the rise in temperature will occur at the same time as the rise in temperature of the OVC bore tube.

By applying the compensating material to the gradient coil assembly, where it will experience a greater variation in temperature, it may be possible to achieve a desired level of compensation with a reduced quantity of compensating material.

Similarly, the compensating material could be applied to the inner surface—the bore surface—of the gradient coil assembly. Even less compensating material would then be required, due to the reduced surface area. The inner surface of the gradient coil assembly may experience an even greater variation in temperature, which may further reduce the mass of compensation material required.

In another variation, the compensating material may be provided as a powder mixed into a resin used in the gradient coil assembly.

Depending on the magnitude of the thermal variation of susceptibility of the OVC bore tube, and the chosen compensating material, it may not be necessary to cover a whole surface of the OVC bore tube or gradient coil assembly with compensating material. Instead, the compensating material may be applied as patches over a surface of the OVC or gradient coil assembly. This could be achieved by screen printing or stenciling of a paint containing the compensating material, or application of sheets of non-magnetic material containing compensating material, such as sheets of polyester with embedded NiO or NiFeMn powder. This may be conveniently supplied and applied as a self-adhesive sheet which may be cut to size before application to a chosen part of the surface of the OVC or gradient coil assembly.

In further embodiment, a complete cylinder of non-magnetic material may be produced with embedded compensating material such as NiO or NiFeMn powder, the cylinder being slid over the gradient coil assembly during production. Alternatively, the cylinder may be dimensioned to fit inside the gradient coil assembly as a liner. Similarly, such cylinders may be arranged to fit the radially outer surface of the OVC bore tube and be positioned during assembly of the OVC, or may be dimensioned to fit inside the OVC bore tube as a liner.

In embodiments using paint or compensating material embedded in a nonmagnetic carrier, care should be taken to ensure an even distribution of compensating material. For materials such as FeRh, which have a high variation in magnetic moment, the concentration of the compensating material in the paint or the nonmagnetic carrier may be relatively dilute, so that extra care should be taken to ensure an even distribution of the compensating material.

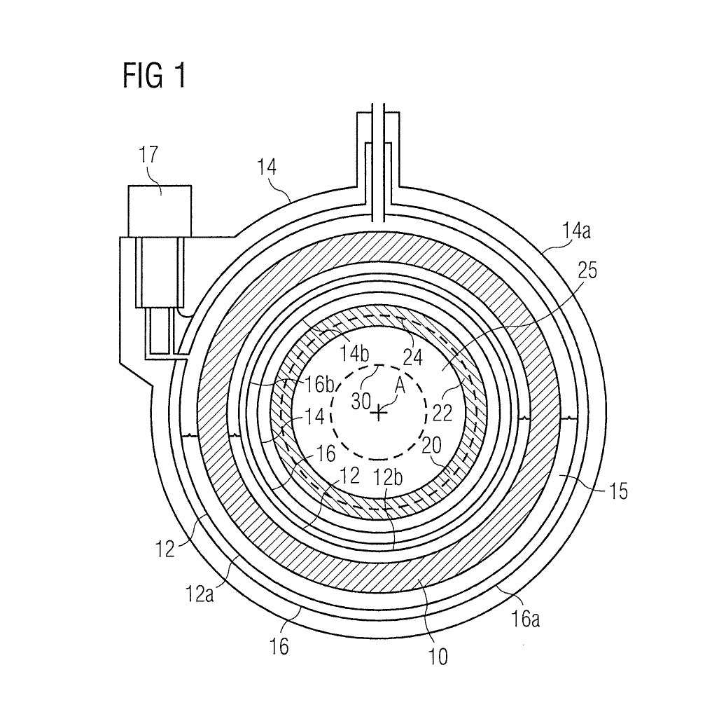

In alternative embodiments, the shimming arrangements of the MRI system may be used to accommodate compensating material. In typical conventional systems such as shown in FIG. 1, the gradient coil assembly 22 is provided with shim slots 24, and shim trays (not shown) containing a number of shims in the form of planar sheets of iron, are slid into the shim slots to improve the homogeneity of the background field in the imaging region. These arrangements may be employed in certain embodiments of the present invention.

For example, powdered compensating material may be embedded within the material of the shim trays. When in use, the shim trays surround the imaging region are subjected to a change in temperature greater than that of the OVC bore tube, but occurring at the same time.

Alternatively, one or more surfaces of the shim trays may be painted with a paint containing powdered compensating material, or sheets of non-magnetic material containing powdered compensating material may be applied to surfaces of the shim trays. Sheets of nonmagnetic material painted or embedded with compensating material may be placed inside shim tray pockets in the same manner as conventional shims.

The magnetic properties of antiferromagnets do depend on the orientation of the “easy axis” to the applied field. The ‘easy axis’ is determined by the magnetocrystalline anisotropy of an antiferromagnet. The increase in susceptibility with temperature will be larger when the field is parallel to the easy axis.

While nickel oxide NiO can be used as a compensating material, it may be found that significant quantities are required. Solid blocks of NiO may be placed at selected locations on a radially outer or radially inner surface of the OVC bore tube 14b or the gradient coil assembly 22.

The invention accordingly provides compensation for magnetic field drift caused by temperature variations in the material of an OVC bore tube in a superconducting magnet by addition of a compensating material having a complementary thermal variation in magnetic susceptibility. In particular, the added compensating material may have a phase-change property as described above.

The compensating material added according to the present invention may also compensate for drift in magnetic field strength due to change in magnetic properties of other parts of the magnet structure, not only the OVC bore tube. Nevertheless, the variation of temperature of the OVC bore tube 14b is the principle cause of B₀ drift addressed by the present invention.

Advantageously, the B₀ drift compensation provided by the present invention does not require a change in the original material used for the OVC bore tube, and does not require the provision and operation of a cooling arrangement for the OVC bore tube. The present invention provides a passive arrangement which requires no maintenance or operation when in use, yet provides compensation for the majority of B₀ drift.

While certain compensating materials have been suggested, by way of examples only, those skilled in the art will be able to determine other compensating materials which may be used in embodiments of the present invention.

Ferrimagnetic materials may be used, which have a small magnetic susceptibility that increases in temperature.

Antiferromagnetic materials may be used, which have a magnetic susceptibility that increases in temperature up to a certain point, called the Néel temperature.

A material is required which undergoes a positive change in magnetic susceptibility with rising temperature to compensate a falling magnetic susceptibility of stainless steel.

The present invention is particularly applicable to stainless steel OVC bore tubes, as other materials which may be used, such as aluminum or titanium, undergo only a small change in susceptibility in the temperature range of interest Mild steel may be used as a material for an OVC bore tube. FeRh could be used as a compensating material for a mild steel OVC bore tube.

The compensating material chosen should have a large enough change in magnetic moment to achieve the required compensation with a reasonable quantity of material. For example, using NiFeMn alloys, a 2.5 mm layer of powdered compensation material in an epoxy carrier may be found sufficient. FeRh has a much larger change in magnetic moment over the temperature change of interest, but the material is more difficult and costly to obtain in the required quantities. While certain locations for positioning of the compensating material have been proposed, any position may be found suitable provided that it lies at a radial position between the imaging region and the magnet (10) in a location which will be heated during operation of the MRI system.

Although modifications and changes may be suggested by those skilled in the art, it is the intention of the inventor to embody within the patent warranted hereon all changes and modifications as reasonably and properly come within the scope of his contribution to the art.

I claim as my invention:

1. A magnetic resonance imaging (MRI) system comprising:
a cylindrical superconducting magnet assembly having a longitudinal axis;
a cylindrical vacuum vessel (OVC) that contains the superconducting magnet assembly, said OVC having a bore tube therein comprised of bore tube material having a magnetic susceptibility and that is rotationally symmetrical about the longitudinal axis;
a gradient coil assembly situated within the bore tube of the OVC, said gradient coil assembly having a coil assembly bore therein;
said superconducting magnet assembly being configured to produce a magnetic field in an imaging region within said bore tube of said gradient coil assembly, said magnetic field in said imaging region exhibiting a field property that is subject to drift due to heating that occurs during operation of said MRI system that causes said magnetic susceptibility of said bore tube material to change;
compensating material situated at a radial position, relative to said longitudinal axis, between the imaging region and the superconducting magnet assembly at a location that is subject to heating over a range of temperatures due to said heating that occurs during said operation of the MRI system; and
said compensating material having a magnetic susceptibility that changes with temperature, within said range of temperature oppositely to said change in magnetic susceptibility of said bore tube material, to compensate said drift.

2. An MRI system as claimed in claim 1 wherein said bore tube of said OVC is comprised of stainless steel.

3. An MRI system as claimed in claim 2 wherein the compensating material comprises ferrimagnetic nickel-iron vanadates (NiFe₂-xVₓO₄).

4. An MRI system as claimed in claim 2 wherein the compensating material comprises antiferromagnetic nickel oxide NiO.

5. An MRI system as claimed in claim 2 wherein the compensating material comprises an alloy of iron and manganese.

6. An MRI system as claimed in claim 2 wherein the compensating material comprises an alloy of iron, nickel and manganese.

7. An MRI system as claimed in claim 6 wherein the compensating material comprises Fe₆₅(Ni₁₋ₓMnₓ)₃₅.

8. An MRI system as claimed in claim 7 wherein the compensating material comprises Fe₆₅(Ni₃₀Mn₇₀)₃₅.

9. An MRI system as claimed in claim 2 wherein the compensating material comprises an alloy of iron and rhodium (FeRh).

10. An MRI system as claimed in claim 1 wherein said compensating material is formed as selected masses of said compensating material situated at the bore tube of the OVC at selected locations.

11. An MRI system as claimed in claim 1 wherein said compensating material is comprised in a coating on a radially outer surface of the bore tube of the OVC.

12. An MRI system as claimed in claim 1 wherein said compensating material is comprised in a coating on a radially inner surface of the bore tube of the OVC.

13. An MRI system as claimed in claim 1 wherein said compensating material is comprised in a coating on a radially outer surface of the gradient coil assembly.

14. An MRI system as claimed in claim 1 wherein said compensating material is comprised in a coating on a radially inner surface of the gradient coil assembly.

15. An MRI system as claimed in claim 1 comprising shim material contained in shim trays housed within said gradient coil assembly, and wherein said compensating material is comprised in a coating on at least one surface of at least one of said shim trays, and wherein said controllable heater is configured to heat said coating.

16. An MRI system as claimed in claim 15 wherein said coating comprises said compensating material as a powder in an epoxy resin carrier.

17. An MRI system as claimed in claim 1 comprising shim material contained in shim trays situated within respective shim slots in said gradient coil assembly, and wherein said compensating material is embedded as a powder within material forming said shim trays, and wherein said heater is configured to heat said compensating material embedded within said material of said shim trays.

18. An MRI system as claimed in claim 1 comprising shim material contained in shim trays positioned within shim slots in said gradient coil assembly, and wherein said compensating material is formed as at least one patch situated on a surface selected from the group consisting of a surface of the OVC, a surface of at least one of said shim trays, and a surface of said gradient coil assembly.

19. An MRI system as claimed in claim 18 wherein said at least one patch comprises a self-adhesive sheet applied to said surface.

20. An MRI system as claimed in claim 1 wherein said compensating material is comprised in a coating on a radially inner surface of the gradient coil assembly.

21. An MRI system as claimed in claim 1 comprising a complete cylinder of non-magnetic material situated inside said bore of said gradient coil assembly as a liner, and wherein said cylinder of non-magnetic material comprises said compensating material embedded therein.

22. An MRI system as claimed in claim 1 comprising a complete cylinder of non-magnetic material situated around said bore tube of said OVC, said cylinder of non-magnetic material comprising said compensating material embedded therein.

23. An MRI system as claimed in claim 1 comprising a complete cylinder of non-magnetic material situated inside said bore tube of said OVC, said cylinder of non-magnetic material comprising said compensating material embedded therein.

24. An MRI system as claimed in claim 1 comprising shim material contained in shim trays positioned within shim slots in said gradient coil assembly, said shim material being formed as sheets, and wherein said MRI system comprises sheets of non-magnetic material coated or embedded with said compensating material, said sheets of non-magnetic material conforming to said sheets of shim material and being situated in said shim trays together with said shim material.

25. An MRI system as claimed in claim 1 comprising shim material contained in shim trays positioned within shim slots in said gradient coil assembly, said shim material being formed as sheets, and wherein said MRI system comprises sheets of non-magnetic material coated or embedded with said compensating material, said sheets of non-magnetic material conforming to said sheets of shim material and being situated in said shim trays together with said shim material.

26. An MRI system as claimed in claim 1 wherein said bore tube of said OVC is comprised of mild steel.

27. An MRI system as claimed in claim 1 wherein said compensating material comprises an iron-rhodium alloy.

28. A method for operating an MRI system comprising a cylindrical superconducting magnet assembly having a longitudinal axis, a cylindrical vacuum vessel (OVC) that contains the superconducting magnet assembly, said OVC having a bore tube therein comprised of bore tube material having a magnetic susceptibility and that is rotationally symmetrical about the longitudinal axis, a gradient coil assembly situated within the bore tube of the OVC, said gradient coil assembly having a coil assembly bore therein, said superconducting magnet assembly being configured to produce a magnetic field in an imaging region within said bore tube of said gradient coil assembly, said magnetic field in said imaging region exhibiting a field property that is subject to drift due to heating that occurs during operation of said MRI system that causes said magnetic susceptibility of said bore tube material to change, said method comprising:
situating compensating material at a radial position, relative to said longitudinal axis, between the imaging region and the superconducting magnet assembly at a location that is subject to heating over a range of temperatures due to said heating that occurs during said operation of the MRI system; and
selecting said compensation material to have a magnetic susceptibility that changes with temperature, within said range of temperature oppositely to said change in magnetic susceptibility of said bore tube material, to compensate said drift.

29. A method as claimed in claim 28 comprising forming said compensating material as selected masses of said compensating material, and situating said masses at the bore tube of the OVC at selected locations.

30. A method as claimed in claim 28 comprising situating said compensating material in a coating on a radially outer surface of the bore tube of the OVC.

31. A method as claimed in claim 28 comprising situating said compensating material in a coating on a radially inner surface of the bore tube of the OVC.

32. A method as claimed in claim 28 comprising situating said compensating material in a coating on a radially outer surface of the gradient coil assembly.

33. A method as claimed in claim 28 comprising situating said compensating material in a coating on a radially inner surface of the gradient coil assembly.

34. A method as claimed in claim 28 comprising housing shim material contained in shim trays within said gradient coil assembly, and situating said compensating material in a coating on at least one surface of at least one of said shim trays.

35. A method as claimed in claim 34 comprising embodying said compensating material as a powder in an epoxy resin carrier in said coating.

36. A method as claimed in claim 28 comprising housing shim material contained in shim trays situated within respective shim slots in said gradient coil assembly, and embedding said compensating material as a powder within material forming said shim trays.

37. A method as claimed in claim 28 comprising housing shim material contained in shim trays positioned within shim slots in said gradient coil assembly, and situating said compensating material as at least one patch on a surface selected from the group consisting of a surface of the OVC, a surface of at least one of said shim trays, and a surface of said gradient coil assembly.

38. A method as claimed in claim 37 comprising applying said at least one patch to said surface as a self-adhesive sheet.

39. A method as claimed in claim 28 comprising forming said compensating material as iron-rhodium having a composition Fe(100-x)Rhx, wherein 51≦x≦60.

40. A method as claimed in claim 28 comprising forming said compensating material as magnesium bismuth MgBi.

41. A method as claimed in claim 28 comprising forming said compensating material as at least one metal monoxide.

42. A method as claimed in claim 28 wherein said MRI system comprises a complete cylinder of non-magnetic material situated around said gradient coil assembly, and embedding said compensating material in said cylinder of non-magnetic material.

43. A method as claimed in claim 28 wherein said MRI system comprises a complete cylinder of non-magnetic material situated inside said bore of said gradient coil assembly as a liner, and embedding said compensating material in said cylinder of non-magnetic material.

44. A method as claimed in claim 28 wherein said MRI system comprises a complete cylinder of non-magnetic material situated around said bore tube of said OVC, and embedding said compensating material in said cylinder of non-magnetic material comprising said compensating material embedded therein.

45. A method as claimed in claim 28 wherein said MRI system comprises a complete cylinder of non-magnetic material situated inside said bore tube of said OVC, and embedding said compensating material in said cylinder of non-magnetic material.

46. A method as claimed in claim 28 wherein said gradient coil assembly comprises a resin, and comprising providing said compensating material as a powder within said resin.

47. A method as claimed in claim 28 comprising housing shim material contained in shim trays positioned within shim slots in said gradient coil assembly, said shim material being formed as sheets, and wherein said MRI system comprises sheets of non-magnetic material conforming to said sheets of shim material, said sheets of non-magnetic material being situated in said shim trays together with said shim material, and coating said sheets of non-magnetic material with said compensating material or embedding said compensating material in said sheets of non-magnetic material.

48. A method as claimed in claim 28, comprising selecting the compensating material to comprise NiO situating said compensating material as form solid blocks placed at selected locations on a radially outer or radially inner surface of the OVC or the gradient coil assembly.
